(19) United States
(12) Patent Application Publication
(10) Pub. No.: US 2007/0117247 A1
(43) Pub. Date: May 24, 2007

(54) Manufacturing method of microstructure

(75) Inventors: Hsin-Chang Tsai, Taoyuan Hsien (TW); Yu-Ru Chang, Taoyuan Hsien (TW); Tai-Kang Shing, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/594,116

(22) Filed: Nov. 8, 2006

(30) Foreign Application Priority Data
Nov. 23, 2005 (TW) 094141108

(51) Int. Cl. H01L 21/00

(52) U.S. Cl. 438/53

(57) ABSTRACT

A manufacturing method of a microstructure includes the steps of: providing a substrate; forming a photoresist layer on the substrate; providing a first mask, which has at least one opaque area and at least one first lens, over the photoresist layer; providing a light source for illuminating the photoresist layer through the first mask; removing a portion of the photoresist layer to form at least one recess having a lateral wall, a depth and a width. An inclined angle of the lateral wall is not less than 5 degrees and the ratio of the depth to the width is not less than 2.

### CROSS REFERENCE TO RELATED APPLICATIONS

This Non-provisional application claims priority under 35 U.S.C. §119(a) on Patent Application No(s). 094141108 filed in Taiwan, Republic of China on Nov. 23, 2005, the entire contents of which are hereby incorporated by reference.

### BACKGROUND OF THE INVENTION

1. Field of Invention

The invention relates to a manufacturing method of a microstructure and, in particular, to a manufacturing method for a microstructure with a high aspect ratio.

2. Related Art

An inclined lateral wall structure is frequently seen in a micro electromechanical system (MEMS), and may serve as a contact plug or a via plug, or may be applied to form a precision mold. The conventional manufacturing method for the inclined lateral wall structure is usually performed by way of mechanical machine processing, such as planing, polishing, laser processing or electricity discharge processing.

FIGS. 1A to 1C are schematic illustrations showing a conventional manufacturing process for a conventional inclined lateral wall structure. As shown in FIG. 1A, a workpiece 10 having a surface 101 is provided, and a tool 11 having an inclined surface 111 is selected. Next, as shown in FIG. 1B, the tool 11 is used to processing the surface 101 of the workpiece 10 by way of, for example, cutting, polishing, or planing. Finally, after the processing procedures have been finished, a recess C1 with an inclined lateral wall is formed on the workpiece 10.

However, the above-mentioned processing method is restricted by the size and the precision of the tool itself, and cannot easily form an inclined lateral wall structure with high-precision, high-resolution and low surface roughness in the micro electromechanical system, so the technological threshold and cost are very high. Thus, it is an important subject to provide a method for manufacturing a microstructure with high-precision, high-resolution and low surface roughness in the micro electromechanical system. Also, it is an important subject to provide a method for manufacturing a microstructure to make the batch production possible and reduce production cost.

### SUMMARY OF THE INVENTION

In view of the foregoing, the invention is to provide a manufacturing method of a microstructure with high-precision, high-resolution and low surface roughness, wherein the method makes the batch production possible, shortens the manufacturing time and reduces production cost.

To achieve the above, the invention discloses a manufacturing method of a microstructure. The method includes the steps of: providing a substrate, forming a photoresist layer on the substrate, providing a first mask, which includes at least one opaque area and at least one first lens, over the photoresist layer, providing a light source to illuminate the photoresist layer through the first mask, and removing a portion of the photoresist layer to form at least one recess in the photoresist layer. The recess has a lateral wall, a depth and a width. An inclined angle of the lateral wall is not less than 5 degrees, and a ratio of the depth to the width is not less than 2.

To achieve the above, the invention also discloses a manufacturing method of a microstructure. The method includes the steps of: providing a substrate, which has a surface including at least one opaque area and at least one first lens, forming a photoresist layer on the surface of the substrate, providing a light source to illuminate the photoresist layer through the substrate, and removing a portion of the photoresist layer to form at least one recess in the photoresist layer. The recess has a lateral wall, a depth and a width. An inclined angle of the lateral wall is not less than 5 degrees, and a ratio of the depth to the width is not less than 2.

As mentioned above, the manufacturing method of the microstructure according to the invention is to dispose the photoresist layer on the substrate and then to form the microstructure using a semiconductor process (e.g., a photo-lithographic process). Therefore, the resolution, precision and surface roughness of the microstructure are better than those of the conventional microstructures which are formed by using prior art processing methods. According to the advantage of the semiconductor process, the microstructure can be produced in batches, and the manufacturing time and cost may be reduced.

### BRIEF DESCRIPTION OF THE DRAWINGS

The invention will become more fully understood from the detailed description given herein below illustration only, and thus is not limitative of the present invention, and wherein:

FIGS. 1A to 1C are schematic illustrations showing a conventional manufacturing method for a conventional inclined lateral wall structure;

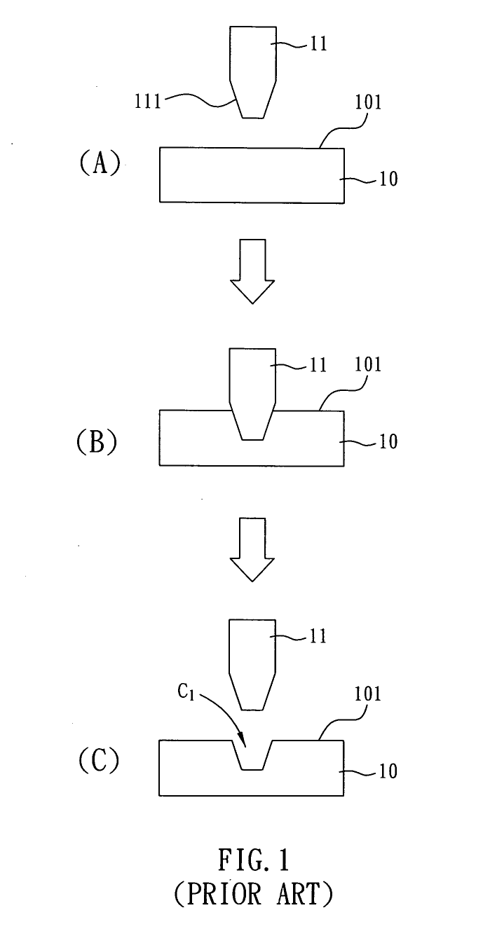

FIGS. 2A to 2E are schematic illustrations showing the procedures of a manufacturing method of a microstructure according to a first embodiment of the invention;

FIGS. 3A and 3B are schematic illustrations showing the procedures of a manufacturing method of a microstructure according to another first embodiment of the invention;

FIGS. 4A to 4G are schematic illustrations showing the procedures of a manufacturing method of a microstructure according to a second embodiment of the invention;

FIGS. 5A to 5D are schematic illustrations showing the procedures of a manufacturing method of a microstructure according to a third embodiment of the invention; and

FIGS. 6A to 6F are schematic illustrations showing the procedures of a manufacturing method of a microstructure according to a fourth embodiment of the invention.

### DETAILED DESCRIPTION OF THE INVENTION

The present invention will be apparent from the following detailed description, which proceeds with reference to the accompanying drawings, wherein the same references relate to the same elements.

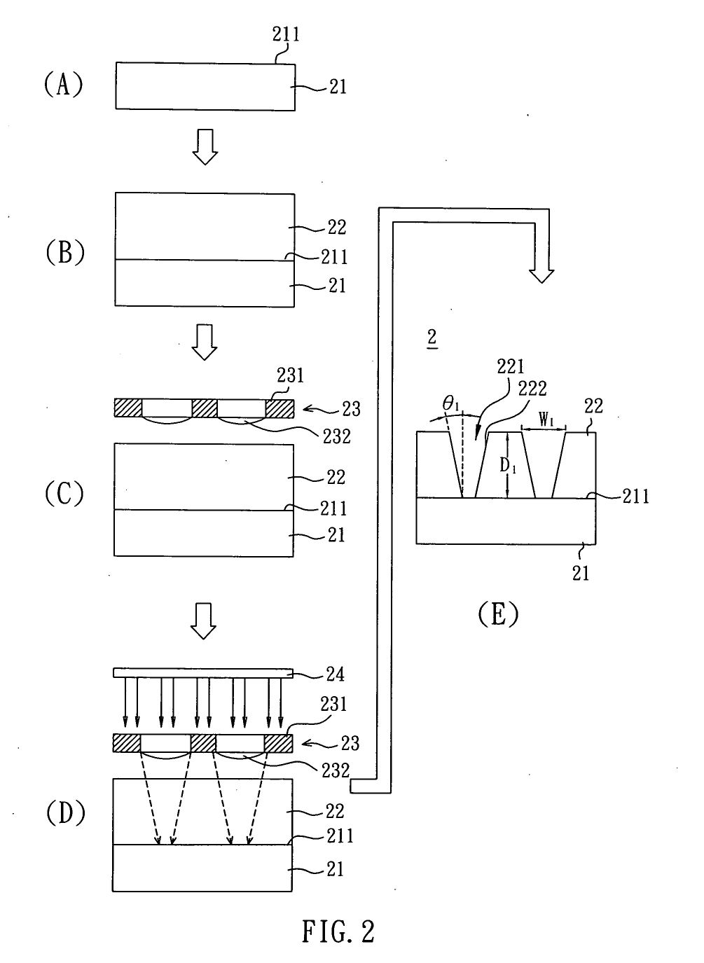

Referring to FIGS. 2A to 2E, a manufacturing method of a microstructure according to a first embodiment of the invention includes the following steps. As show in FIG. 2A, a substrate 21 having a surface 211 is firstly provided. In this embodiment, the substrate 21 may be a light-permeable substrate, a translucent substrate or an opaque substrate.

Next, as shown in FIG. 2B, a photoresist layer 22 is formed on the surface 211 of the substrate 21. In this embodiment, the photoresist layer 22 is made of a positive photosensitive material, and the thickness of the photoresist layer 22 is not less than 0.03 mm. It is noted that the material of the photoresist layer 22 is not limited to the positive photosensitive material. Instead, the photoresist layer 22 may be made of a negative photosensitive material, a single-layer photosensitive material or a multi-layer photosensitive material. The photosensitive material of the photoresist layer 22 and the number of the photoresist layer(s) 22 may be selected according to actual requirements.

Next, as shown in FIG. 2C, a first mask 23 is provided over the photoresist layer 22. The first mask 23 has an opaque area 231 and a first lens 232, both of which are alternately arranged on a surface of the first mask 23. In this embodiment, the first lens 232 is a focusing lens.

Then, as shown in FIG. 2D, a light source 24 is provided to illuminate the photoresist layer 22 through the first mask 23.

Finally, as shown in FIG. 2E, a portion of the photoresist layer 22 is removed such that a recess 221 is formed in the photoresist layer 22. The recess 221 has a lateral wall 222, a depth D1 and a width W1. An inclined angle θ1 of the lateral wall 222 is not less than 5 degrees, and a ratio of the depth D1 to the width W1 is not less than 2.

The recess 221 is formed by a photo-lithographic process. Because the photoresist layer 22 is made of the positive photosensitive material, the portion illuminated by the light source 24 is formed into the recess 221 after the photo-lithographic process is performed. The photo-lithographic process pertains to the typical semiconductor process that is often used, and the removing of a portion of the photoresist layer 22 may be performed by way of development, which is the typical semiconductor process that is usually adopted, so detailed descriptions thereof will be omitted.

In this embodiment, the depth D1 of the recess 221 is not less than 0.03 mm. The depth D1 of the recess 221 substantially equals to the thickness (0.03 mm) of the photoresist layer 22. Under the definition that the ratio of the depth D1 to the width W1 is not less than 2, the width W1 of the recess 221 is not greater than 0.015 mm, the feature size of the recess 221 is not greater than 0.5 mm, and the processing precision is not greater than 0.01 mm.

The inclined angle θ1 of the recess 221 is formed according to a focusing phenomenon obtained when the light source 24 illuminates the photoresist layer 22 through the first lens 232. The first lens 232 of this embodiment is a focusing lens, so the light rays of the light source 24 pass through the first lens 232 and are then focused, as shown in FIG. 2D. Thus, the inclined angle θ1 of the lateral wall 222, which is generated when a portion of the photoresist layer 22 is removed, may be controlled in order to form the recess 221.

A microstructure 2, as shown in FIG. 2E, to be applied to a micro electromechanical system may be manufactured according to the above-mentioned manufacturing method. The microstructure 2 includes the substrate 21 and the photoresist layer 22. The substrate 21 has the surface 211. The photoresist layer 22 is disposed on the surface 211 of the substrate 21. The photoresist layer 22 has at least one recess 221, which has the lateral wall 222, the depth D1 and the width W1. In addition, the lateral wall 222 of the recess 221 with the inclined angle θ1 may be symmetrically arranged or non-symmetrically arranged. That is, the inclined angle θ1 of the lateral wall 222 of the recess 221 can be changed according to actual requirements.

In the above-mentioned embodiment, the first mask 23 has, without limitation to, one opaque area 231 and one first lens 232. It is also possible to utilize a mask (not shown) used in the typical photo-lithographic process in conjunction with a light modulation device (not shown) to achieve the same effect and object as those of the first mask 23. The light modulation device may be a lens or a liquid lens, and the lens may also be a focusing lens or a defocusing lens. Thus, the light rays passing through the mask can define the exposure positions. Meanwhile, by using the light modulation device can change the focusing or defocusing phenomenon of the light rays and thus achieve the same effect.

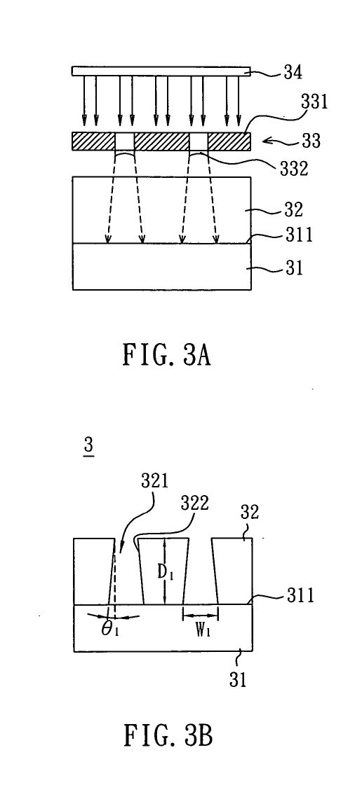

FIGS. 3A and 3B are schematic illustrations showing the procedures of a manufacturing method of a microstructure according to another first embodiment of the invention. In FIG. 3A, a first lens 332 of a first mask 33 is a defocusing lens, so the light rays of a light source 34 pass through the first lens 332 and are then defocused. Thus, it is possible to control the inclined angle θ1 of a lateral wall 322, when a portion of a photoresist layer 32 is removed, to form a recess 321 such that a microstructure 3 is formed, as shown in FIG. 3B.

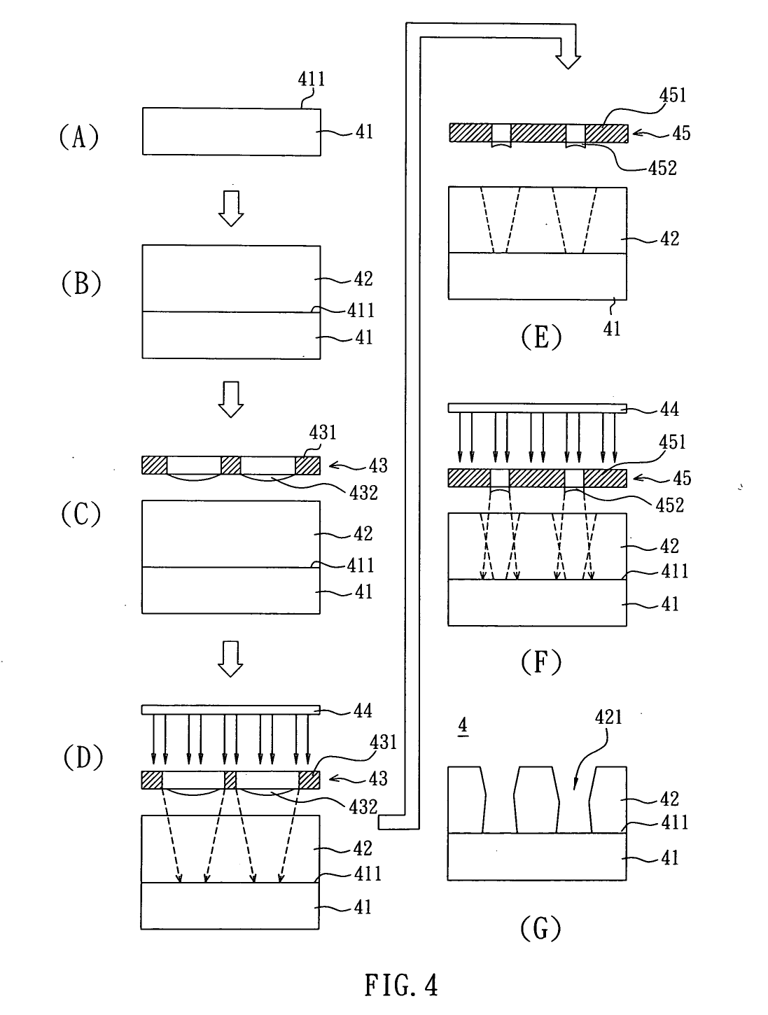

FIGS. 4A to 4G are schematic illustrations showing the procedures of a manufacturing method of a microstructure according to a second embodiment of the invention. Referring to FIGS. 4A to 4G, the manufacturing method includes the following steps. In the second embodiment, the steps of FIGS. 4A to 4D are the same as those of FIGS. 2A to 2D, so detailed descriptions thereof will be omitted.

As shown in FIG. 4E, the difference between this embodiment and the first embodiment is that a second mask 45 is provided over a photoresist layer 42 after the step described and shown in FIG. 4D. The second mask 45 has an opaque area 451 and a second lens 452, which are arranged on the surface of the second mask 45 alternately. In this embodiment, the second lens 452 is a defocusing lens.

Next, as shown in FIG. 4F, a light source 44 is provided to illuminate the photoresist layer 42 through the second mask 45.

Finally, as shown in FIG. 4G, a portion of the photoresist layer 42 is removed to form a recess 421 in the photoresist layer 42 and thus to form a microstructure 4. In this embodiment, the recess 421 is formed after two exposing procedures. Because the photoresist layer 42 is a positive photosensitive material, the portion illuminated by the light source 44 is formed into the recess 421 after the photo-lithographic process, and the microstructure 4 is thus formed.

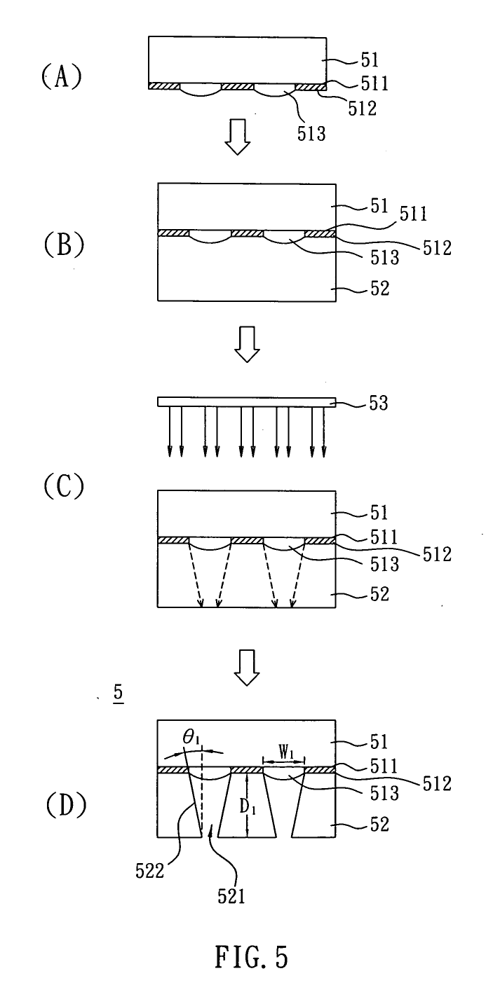

A manufacturing method of a microstructure according to a third embodiment of the invention includes the following steps. As shown in FIG 5A, a substrate 51 having a surface 511 is firstly provided. The surface 511 has an opaque area 512 and a first lens 513. In this embodiment, the substrate 51 may be a light-permeable substrate or a translucent substrate, and the first lens 513 is a focusing lens.

As shown in FIG 5B, a photoresist layer 52 is formed on the surface 511 of the substrate 51. In this embodiment, the photoresist layer 52 is made of a positive photosensitive material, and the thickness of the photoresist layer 52 is not less than 0.03 mm.

Next, as shown in FIG 5C, a light source 53 is provided to illuminate the photoresist layer 52 through the substrate 51.

Finally, as shown in FIG 5D, a portion of the photoresist layer 52 is removed to form at least one recess 521 in the photoresist layer 52, and thus to form a microstructure 5. In addition, the recess 521 has a lateral wall 522, a depth D1 and a width W1, an inclined angle θ1 of the lateral wall 522 is not less than 5 degrees, and a ratio of the depth D1 to the width W1 is not less than 2. In this embodiment, the recess 521 is formed by a photo-lithographic process. Because the photoresist layer 52 is made of a positive photosensitive material, the portion illuminated by the light source 53 is formed into the recess 521 after the photo-lithographic process.

The depth D1 of the recess 521 is not less than 0.03 mm. In this embodiment, the depth D1 of the recess 521 and the thickness of the photoresist layer 52 are 0.03 mm. Under the definition that the ratio of the depth D1 to the width W1 is not less than 2, the width W1 of the recess 521 is not greater than 0.015 mm. In this embodiment, the feature size of the recess 521 is not greater than 0.5 mm, and the processing precision is not greater than 0.01 mm.

The inclined angle θ1 of the recess 521 is formed through a focusing phenomenon, which is generated after the light source 53 illuminates the photoresist layer 52 through the first lens 513. The first lens 513 of this embodiment is a focusing lens. Thus, the focusing effect (FIG 5C), which is generated after the light rays of the light source 53 pass through the first lens 513, can control the inclined angle θ1 of the lateral wall 522 when a portion of the photoresist layer 52 is removed. Then, the recess 521 is formed. Of course, the first lens 513 may also be a defocusing lens in this embodiment.

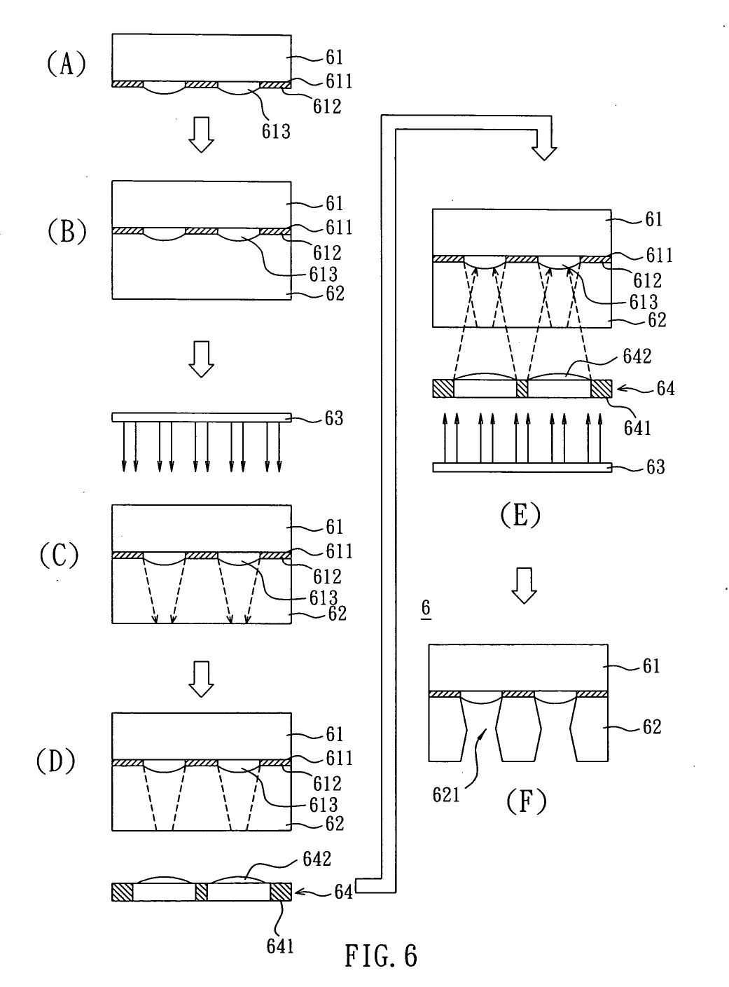

FIGS. 6A to 6F are schematic illustrations showing the procedures of a manufacturing method of a microstructure according to a fourth embodiment of the invention. The manufacturing method of the microstructure includes the following steps. In the fourth embodiment, the steps of FIGS. 6A to 6C are the same as those of FIGS. 5A to 5C, and detailed descriptions thereof will be omitted.

As shown in FIG. 6D, the difference between this embodiment and the third embodiment is that a mask 64 is provided over a photoresist layer 62 after the step of FIG. 6C is performed. The mask 64 has an opaque area 641 and a second lens 642, which are arranged on a surface of the mask 64 alternately. In this embodiment, the second lens 642 may be a focusing lens.

Next, as shown in FIG. 6E, a light source 63 is provided to illuminate the photoresist layer 62 through the mask 64.

Finally, as shown in FIG. 6F, a portion of the photoresist layer 62 is removed to form a recess 621 in the photoresist layer 62 and thus to form a microstructure 6. In this embodiment, the recess 621 is formed after two exposing procedures are performed. Because the photoresist layer 62 is made of a positive photosensitive material, the portion illuminated by the light source 63 is formed into the recess 621 after the photo-lithographic procedure. Thus, the microstructure 6 is formed.

In summary, the manufacturing method of the microstructure according to the invention is to dispose the photoresist layer on the substrate and then to form the microstructure by using a semiconductor process (e.g., a photo-lithographic process). Therefore, the resolution, precision and surface roughness of the microstructure are better than those of the conventional microstructures formed by using the prior art processing methods. According to the advantage of the semiconductor process, the microstructure can be produced in batches, and the manufacturing time and cost may be reduced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A manufacturing method of a microstructure, comprising steps of:
providing a substrate;
forming a photoresist layer on the substrate;
providing a first mask over the photoresist layer, wherein the first mask comprises at least one opaque area and at least one first lens;
providing a light source to illuminate the photoresist layer through the first mask; and
removing a portion of the photoresist layer to form at least one recess in the photoresist layer.

2. The method according to claim 1, wherein the first lens is a focusing lens or a defocusing lens.

3. The method according to claim 1, wherein the recess has a lateral wall, a depth and a width, an inclined angle of the lateral wall is not less than 5 degrees, and a ratio of the depth to the width is not less than 2.

4. The method according to claim 3, wherein a feature size of the recess is not greater than 0.5 mm, a processing precision of the recess is not greater than 0.01 mm, the depth is not less than 0.03 mm, or a thickness of the photoresist layer is not less than 0.03 mm.

5. The method according to claim 1, wherein before the step of removing the portion of the photoresist layer, the method further comprises steps of:
providing a second mask over the photoresist layer, wherein the second mask comprises at least one opaque area and at least one second lens; and
using the light source to illuminate the photoresist layer through the second mask.

6. The method according to claim 1, wherein the photoresist layer is made of a positive photosensitive material, a negative photosensitive material, a single-layer photosensitive material or a multi-layer photosensitive material.

7. The method according to claim 1, wherein the recess has two lateral walls, the lateral walls are symmetrically arranged or non-symmetrically arranged, and the substrate is a light-permeable substrate, a translucent substrate or an opaque substrate.

8. The method according to claim 1, wherein the recess is formed by a photo-lithographic process, and the step of removing the portion of the photoresist layer is performed by way of development.

9. A manufacturing method of a microstructure, comprising steps of:
providing a substrate, wherein the substrate has a surface with at least one opaque area and at least one first lens;
forming a photoresist layer on the surface of the substrate;
providing a light source to illuminate the photoresist layer through the substrate; and
removing a portion of the photoresist layer to form at least one recess in the photoresist layer.

10. The method according to claim 9, wherein the first lens is a focusing lens or a defocusing lens.

11. The method according to claim 9, wherein the recess has a lateral wall, a depth and a width, an inclined angle of the lateral wall is not less than 5 degrees, and a ratio of the depth to the width is not less than 2.

12. The method according to claim 11, wherein a feature size of the recess is not greater than 0.5 mm, a processing precision of the recess is not greater than 0.01 mm, the depth is not less than 0.03 mm, or a thickness of the photoresist layer is not less than 0.03 mm.

13. The method according to claim 9, wherein before the step of removing the portion of the photoresist layer, the method further comprises steps of:
providing a mask over the photoresist layer, wherein the mask comprises at least one opaque area and at least one second lens; and
using the light source to illuminate the photoresist layer through the mask.

14. The method according to claim 9, wherein the recess is formed by a photo-lithographic process, and the step of removing the portion of the photoresist layer is performed by way of development.

15. A manufacturing method of a microstructure, comprising steps of:
providing a substrate;
forming a photoresist layer on the substrate;
providing a first mask over the photoresist layer;
providing a light modulation device over the photoresist layer;
providing a light source to illuminate the photoresist layer through the first mask and the light modulation device; and
removing a portion of the photoresist layer to form at least one recess in the photoresist layer.

16. The method according to claim 15, wherein the recess has a lateral wall, a depth and a width, an inclined angle of the lateral wall is not less than 5 degrees, and a ratio of the depth to the width is not less than 2.

17. The method according to claim 16, wherein a feature size of the recess is not greater than 0.5 mm, a processing precision of the recess is not greater than 0.01 mm, the depth is not less than 0.03 mm, or a thickness of the photoresist layer is not less than 0.03 mm.

18. The method according to claim 15, wherein the light modulation device is a focusing lens, a defocusing lens or a liquid lens.

19. The method according to claim 15, wherein the recess is formed by a photo-lithographic process, and the step of removing the portion of the photoresist layer is performed by way of development.
